(19) United States
(12) Patent Application Publication
(10) Pub. No.: US 2012/0147543 A1
(43) Pub. Date: Jun. 14, 2012

(54) MODULAR DATA CENTER

(75) Inventors: TSUNG-HAN SU, Tu-Cheng (TW); ZEU-CHIA TAN, Tu-Cheng (TW); TAI-WEI LIN, Tu-Cheng (TW)

(73) Assignee: HON HAI PRECISION INDUSTRY CO., LTD., Tu-Cheng (TW)

(21) Appl. No.: 12/975,281

(22) Filed: Dec. 21, 2010

(30) Foreign Application Priority Data
Dec. 9, 2010 (TW) 99143022

(51) Int. Cl. H05K 5/02

(52) U.S. Cl. 361/679.31

(57) ABSTRACT

A modular data center includes a container and a heat-dissipating control system. The container defines an opening with a cover rotatably mounted to the container to cover or uncover the opening when needed to assist in dissipating heat. The heat-dissipating control system includes a temperature sensor, a comparison unit, and a driving device. The temperature sensor is used to sense a temperature in the container, and output a sensed temperature value. The comparison unit is used to receive the sensed temperature value, and compare the sensed temperature value with a first predetermined temperature value. When the sensed temperature value is greater than or equal to the first predetermined temperature value, the comparison unit outputs a control signal. The driving device is used to open the cover to expose the opening after receiving the first control signal.

### BACKGROUND

1. Technical Field

The present disclosure relates to heat dissipation in a modular data center.

2. Description of Related Art

Keeping the temperature below 40 degrees Celsius (° C.) in a modular data center helps electronic apparatuses in the modular data center to work normally. Usually, an air intake is defined in a bottom of a container of the modular data center, to provide air to dissipate heat in the modular data center. However, should the air intake become blocked, without operator knowledge, then heat will not be dissipated properly and damage to equipment may occur.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a first schematic view of an exemplary embodiment of a modular data center, the modular data center includes a heat-dissipating control system.

FIG. 2 is a block diagram of an exemplary embodiment of the heat-dissipating control system of FIG. 1.

FIG. 3 similar to FIG. 1, but shows a using state.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

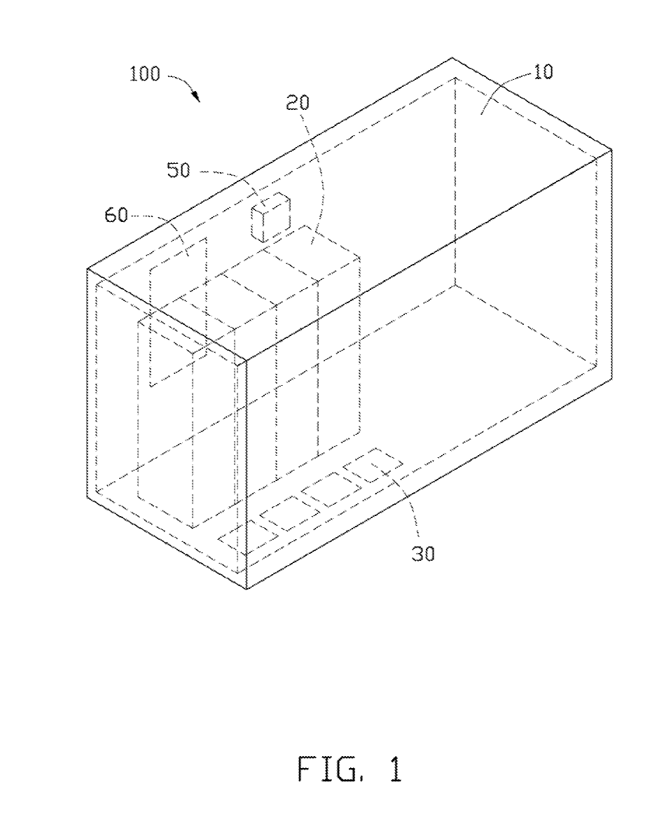

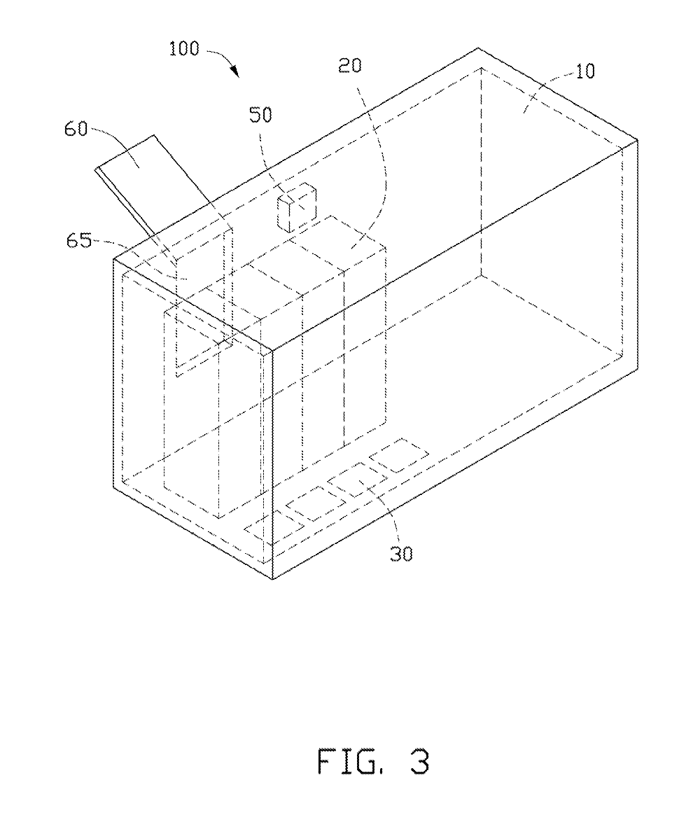

Referring to FIG. 1, an exemplary embodiment of a modular data center 100 includes a container 10, a server module 20, an air intake 30, and a heat-dissipating control system 50. The air intake 30 is defined in a bottom of the container 10 to allow air to enter the container 10, thereby dissipating heat from the server module 20. An opening 65 is defined in a sidewall of the container 10, with a cover 60 (see FIG. 3) rotatably mounted to the container 10 to cover or uncover the opening 65. The heat-dissipating control system 50 is mounted in the container 10. In the embodiment, the modular data center 100 is a mobile container data center.

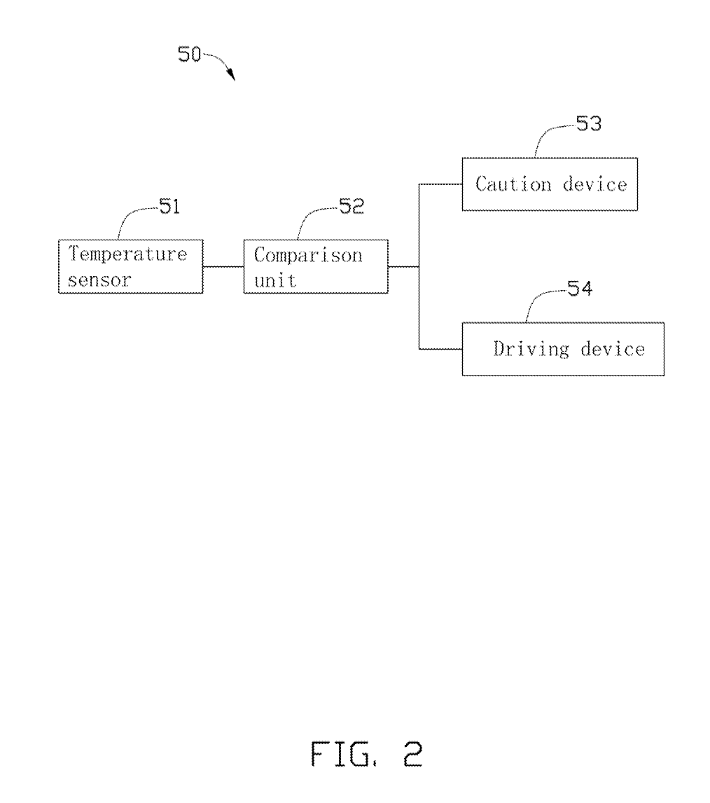

Referring to FIG. 2, the heat-dissipating control system 50 includes a temperature sensor 51, a comparison unit 52, a caution device 53, and a driving device 54. The temperature sensor 51 is used to sense a temperature in the container 10. The temperature sensor 51 is connected to the comparison unit 52 to output a sensed temperature value to the comparison unit 52. The comparison unit 52 is connected to the caution device 53 and the driving device 54. First and second predetermined temperature values are set in the comparison unit 52. In the embodiment, the first predetermined temperature value is 50 degrees. The second predetermined temperature value is 35 degrees.

Referring to FIG. 3, when the comparison unit 52 receives the sensed temperature value, the comparison unit 52 compares the sensed temperature value with the first and second predetermined temperature values. When the sensed temperature value is greater than or equal to the first predetermined value, the comparison unit 52 outputs a first control signal to the driving device 54 and the caution device 53. The driving device 54 opens the cover 60 to uncover the opening 65 after receiving the first control signal, to assist in dissipating heat from the container 10. The caution device 53 is turned on to alert users that there may be a problem with the air intake 30 and the cover 60 had to be opened after receiving the first control signal. When the sensed temperature is lower than the first predetermined temperature value and greater than or equal to the second predetermined temperature value, the comparison unit 52 does not work. When the sensed temperature value is lower than the second predetermined temperature value, the comparison unit 52 outputs a second control signal to the driving device 54. The driving device 54 closes the cover 60 to cover the opening 65 after receiving the second control signal.

In other embodiments, the first and second predetermined temperature values can be adjusted according to need.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. A modular data center comprising:
a container, wherein an opening is defined in the container, with a cover rotatably mounted to the container to cover or uncover the opening when needed to assist in dissipating heat; and
a heat-dissipating control system comprising:
a temperature sensor to sense a temperature in the container, and output a sensed temperature value;
a comparison unit to receive the sensed temperature value, and compare the sensed temperature value with a first predetermined temperature value, wherein when the sensed temperature value is greater than or equal to the first predetermined temperature value, the comparison unit outputs a first control signal; and
a driving device to open the cover to expose the opening after receiving the first control signal, to assist in dissipating heat from the container.

2. The modular data center of claim 1, further comprising a caution device, wherein the caution device is connected to the comparison device, and turned on after receiving the first control signal.

3. The modular data center of claim 1, wherein when the sensed temperature value is lower than the first predetermined temperature value, the comparison unit compares the sensed temperature value with a second predetermined temperature value lower than the first predetermined temperature, when the sensed temperature value is lower than the second predetermined temperature value, the comparison control unit outputs a second control signal to the driving device to close the cover, thereby covering the opening.

4. The modular data center of claim 3, wherein the first predetermined temperature value is 50 degrees, and the second predetermined temperature value is 35 degrees.

5. The modular data center of claim 1, wherein the heat-dissipating control system is mounted in the container.

6. The modular data center of claim 1, wherein the modular data center is a container data center, and the container is mobile.
